(19) United States
(12) Patent Application Publication
(10) Pub. No.: US 2025/0202188 A1
(43) Pub. Date: Jun. 19, 2025

(54) SILICON PHOTONIC CHIP WITH EMBEDDED LASER

(71) Applicant: Nvidia Corporation, Santa Clara, CA (US)

(72) Inventor: Mir Ashkan SEYEDI, Atlanta, GA (US)

(73) Assignee: Nvidia Corporation, Santa Clara, CA (US)

(21) Appl. No.: 18/541,409

(22) Filed: Dec. 15, 2023

(51) Int. Cl. H01S 5/023; H01S 5/026; H01S 5/32

(52) U.S. Cl. CPC H01S 5/023; H01S 5/026; H01S 5/32

(57) ABSTRACT

Silicon photonic chips with embedded lasers and methods for manufacturing silicon photonic chips with embedded lasers are described herein. Some embodiments of the present invention may be directed to a silicon photonic chip including a laser disposed in the silicon photonic chip between a first and second surface of the silicon photonic chip. The laser may include an anode and a cathode each extending substantially parallel to at least one of the first or second surface through at least a portion of the silicon photonic chip. The silicon photonic chip may include a first through-dielectric via electrically connecting the anode to the second surface of the silicon photonic chip and a second through-dielectric via electrically connecting the cathode to the second surface of the silicon photonic chip.

### FIELD OF THE INVENTION

The present invention relates to silicon photonic chips with embedded lasers and methods of making the same.

### BACKGROUND

Optical engines based on silicon include lasers for powering optical links of the engines. Typically, the lasers are not positioned on the chip package with the silicon photonics forming the optical links, but rather the lasers are located remotely from the silicon photonics. The light emitted by the lasers is thus coupled to the chip package using optical fibers, which results in optical losses, increased fiber area, and overall larger optical engine size.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. This summary presents some concepts of one or more embodiments of the present invention in a simplified form as a prelude to the more detailed description that is presented later.

In one aspect, the present invention is directed to a silicon photonic chip including a laser disposed in the silicon photonic chip between a first surface of the silicon photonic chip and a second surface of the silicon photonic chip. The laser may include an anode and a cathode, where each of the anode and the cathode extends substantially parallel to at least one of the first surface or the second surface through at least a portion of the silicon photonic chip. The silicon photonic chip may include a first through-dielectric via electrically connecting the anode to the second surface of the silicon photonic chip. The silicon photonic chip may also include a second through-dielectric via electrically connecting the cathode to the second surface of the silicon photonic chip.

In some embodiments, the laser may be configured to emit light into the silicon photonic chip between the first surface and the second surface.

In some embodiments, the laser may be configured to emit light in a direction substantially parallel to at least one of the first surface or the second surface.

In some embodiments, the laser may include an n-doped region extending substantially parallel to the second surface and through at least a portion of the silicon photonic chip and a p-doped region extending substantially parallel to the second surface and through at least a portion of the silicon photonic chip. Additionally, or alternatively, the laser may include an active region disposed between the n-doped region and the p-doped region, where the active region extends substantially parallel to the second surface and through at least a portion of the silicon photonic chip, and where the active region is configured to generate light. In some embodiments, the laser may include a first mirror region on a first side of the n-doped region, the p-doped region, and the active region and a second mirror region on a second side of the n-doped region, the p-doped region, and the active region, where the second side is opposite the first side.

In some embodiments, the silicon photonic chip may include a silicon waveguide layer disposed within the silicon photonic chip, where the silicon waveguide layer extends substantially parallel to at least one of the first surface or the second surface, and where the silicon waveguide layer is configured to receive and guide light emitted by the laser. Additionally, or alternatively, the silicon photonic chip may include one or more waveguide structures disposed within the silicon photonic chip, where the one or more waveguide structures are configured to direct the light emitted by the laser into the silicon waveguide layer.

In some embodiments, the silicon photonic chip may include a first metal layer extending substantially parallel to at least one of the first surface or the second surface and through at least a portion of the silicon photonic chip, where the first metal layer is electrically connected to the anode and the first through-dielectric via. Additionally, or alternatively, the silicon photonic chip may include a second metal layer extending substantially parallel to at least one of the first surface or the second surface and through at least a portion of the silicon photonic chip, where the second metal layer is electrically connected to the cathode and the second through-dielectric via.

In some embodiments, the silicon photonic chip may include a plurality of metal layers extending substantially parallel to at least one of the first surface or the second surface and through at least a portion of the silicon photonic chip and at least one intra-metal via disposed within the silicon photonic chip and electrically connecting two or more metal layers of the plurality of metal layers, where the plurality of metal layers and the at least one intra-metal via form one or more integrated circuits.

In some embodiments, the silicon photonic chip may include a dielectric encapsulation layer between the first surface of the silicon photonic chip and the second surface of the silicon photonic chip, where the laser is disposed within the dielectric encapsulation layer.

In some embodiments, the silicon photonic chip may include a buried oxide layer, where the buried oxide layer defines the second surface, and where the first through-dielectric via and the second through-dielectric via extend through the buried oxide layer.

In some embodiments, the silicon photonic chip may include metal contacts on the second surface of the silicon photonic chip, where a first metal contact of the metal contacts is electrically connected to the first through-dielectric via, and where a second metal contact of the metal contacts is electrically connected to the second through-dielectric via.

In some embodiments, the silicon photonic chip may include a protective oxide layer, where the protective oxide layer defines the first surface.

In some embodiments, the silicon photonic chip may be an optical interposer.

In some embodiments, an opto-electrical device may include the silicon photonic chip, the opto-electrical device may be electrically connected to the laser via the first through-dielectric via and the second through-dielectric via, and the opto-electrical device may be optically connected to the laser via one or more waveguides.

In another aspect, the present invention may be directed to a method of manufacturing a silicon photonic chip. The method may include forming a cavity in a silicon photonic chip, where the silicon photonic chip has a first surface and a second surface and disposing a laser including an anode and a cathode within the cavity such that each of the anode and the cathode extends substantially parallel to at least one of the first surface or the second surface. The method may include forming a first through-dielectric via to electrically connect the anode to the second surface of the silicon photonic chip and forming a second through-dielectric via to electrically connect the cathode to the second surface of the silicon photonic chip.

In some embodiments, disposing the laser within the cavity may include disposing the laser within the cavity such that an emission axis of the laser is substantially parallel to at least one of the first surface or the second surface.

In some embodiments, the method may include forming a first metal layer in the silicon photonic chip, where the first metal layer extends substantially parallel to at least one of the first surface or the second surface, and where the first metal layer is electrically connected to the anode and the first through-dielectric via. Additionally, or alternatively, the method may include forming a second metal layer in the silicon photonic chip, where the second metal layer extends substantially parallel to at least one of the first surface or the second surface, and where the second metal layer is electrically connected to the cathode and the second through-dielectric via.

In some embodiments, the silicon photonic chip may include a dielectric encapsulation layer between the first surface of the silicon photonic chip and the second surface of the silicon photonic chip, and the method may include, when forming the cavity, forming the cavity in the dielectric encapsulation layer.

In some embodiments, the silicon photonic chip may include a silicon waveguide layer extending substantially parallel to at least one of the first surface or the second surface, and the method may include forming one or more waveguide structures in the silicon photonic chip, where the one or more waveguide structures are configured to direct light emitted by the laser into the silicon waveguide layer.

In some embodiments, the silicon photonic chip may be formed on a silicon substrate adjacent the second surface, and the method may include removing the silicon substrate from the second surface and forming metal contacts on the second surface, where a first metal contact of the metal contacts is electrically connected to the first through-dielectric via, and where a second metal contact of the metal contacts is electrically connected to the second through-dielectric via. Additionally, or alternatively, the method may include reflow soldering the metal contacts to electrically and mechanically connect the silicon photonic chip to a printed circuit board.

The features, functions, and advantages that have been discussed may be achieved independently in various embodiments of the present invention or may be combined with yet other embodiments, further details of which may be seen with reference to the following description and drawings.

### BRIEF DESCRIPTION OF THE DRAWINGS

Having thus described embodiments of the invention in general terms, reference will now be made to the accompanying drawings, wherein:

FIG. 1A is a cross-sectional view of a layer stack for a silicon photonic chip, in accordance with an embodiment of the invention;

FIG. 1B is a cross-sectional view of a layer stack for a laser, in accordance with an embodiment of the invention;

FIG. 2A is a cross-sectional view of a layer stack for a silicon photonic chip with an embedded laser, in accordance with an embodiment of the invention;

FIG. 2B is a cross-sectional view of a layer stack of a chip package including the silicon photonic chip with the embedded laser of FIG. 2A, in accordance with an embodiment of the invention; and

FIG. 3 is a flowchart illustrating a method of manufacturing a silicon photonic chip, in accordance with an embodiment of the invention.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. As used herein, terms such as “upper,” “lower,” “top,” “bottom,” “left,” “right,” etc. are used for explanatory purposes in the examples provided below to describe relative positions, depicted positions, depicted orientations, and/or the like of surfaces, elements, components, portions of components, and/or the like. Also, as used herein, the term “a” and/or “an” shall mean “one or more,” even though the phrase “one or more” is also used herein. Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, a combination of related and unrelated items, etc.), and may be used interchangeably with “one or more.” Where only one item is intended, the phrase “only one” or similar language is used. Also, as used herein, the terms “has,” “have,” “having,” or the like are intended to be open-ended terms. Furthermore, when it is said herein that something is “based on” something else, it may be based on one or more other things as well. In other words, unless expressly indicated otherwise, as used herein “based on” means “based at least in part on” or “based at least partially on.” Also, as used herein, the term “or” is intended to be inclusive when used in a series and may be used interchangeably with “and/or,” unless explicitly stated otherwise (e.g., if used in combination with “either” or “only one of”). Furthermore, as would be evident to one of ordinary skill in the art in view of the present disclosure, the terms “substantially” and “approximately” indicate that the associated description is accurate to within applicable engineering tolerances. Like numbers refer to like elements throughout. No element, act, or instruction used herein should be construed as critical or essential unless explicitly described as such.

As noted above, optical engines based on silicon include lasers for powering optical links of the engines. Typically, the lasers are not positioned on the chip package with the silicon photonics forming the optical links, and the lasers are instead remotely located with respect to the silicon photonics. As such, the light emitted by the lasers is coupled to the chip package using optical fibers, which generally results in optical losses, increased fiber area, and overall larger optical engine size.

Some embodiments of the present invention are directed to a silicon photonic chip that includes a laser embedded within the chip. The laser may be embedded in a dielectric encapsulation layer (e.g., a Back End Of Line silicon nitride layer) in an orientation that is optimal for its performance, namely with its cathode and anode on respective upper and lower surfaces of the laser and with an emission axis substantially parallel to upper and lower surfaces of the laser and the layers of the chip. The anode and cathode of the laser may be electrically connected to horizontal metal layers within the dielectric encapsulation layer.

Through-dielectric vias may extend vertically through the layers of the silicon photonic chip and electrically connect the horizontal metal layers to a bottom surface of the silicon photonic chip (e.g., a bottom surface of a buried oxide layer). In this way, an electrical bias may be applied to the anode and cathode from the bottom surface (e.g., via metal contacts) of the silicon photonic chip to drive the laser to emit light.

The silicon photonic chip may include a silicon waveguide layer and one or more waveguides for coupling the light emitted by the laser into the silicon waveguide layer. The silicon photonic chip may include a protective oxide layer on the dielectric encapsulation layer. The silicon photonic chip may also include a plurality of horizontal metal layers within the dielectric encapsulation layer (e.g., including the metal layers connected to the anode and cathode) and intra-metal vias disposed within the dielectric encapsulation layer for electrically connecting the plurality of metal layers.

Metal contacts may be formed on the bottom surface of the silicon photonic chip to provide electrical connections to the laser's anode and cathode as well as the other components and/or circuitry of the silicon photonic chip. For example, an array of copper pillar bumps may be formed on the bottom surface to form metal contacts, which may be solder-reflowed onto a carrier substrate (e.g., for applying a bias to drive the laser).

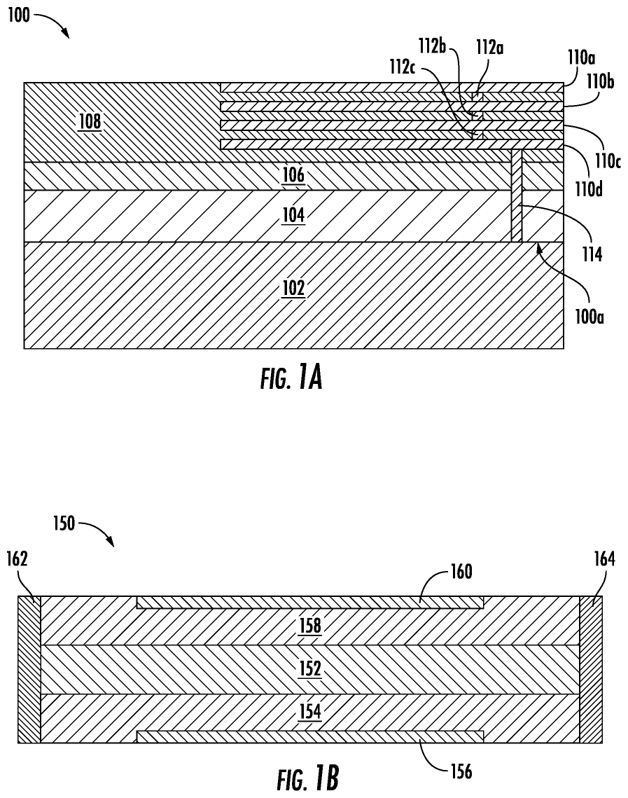

FIG. 1A is a cross-sectional view of a layer stack for a silicon photonic chip 100, in accordance with an embodiment of the invention. As shown in FIG. 1A, the silicon photonic chip 100 may include a bulk silicon layer 102, a buried oxide layer 104, a silicon waveguide layer 106, and a dielectric encapsulation layer 108. As also shown in FIG. 1A, the silicon photonic chip 100 may include a plurality of metal layers 110a-110d, a plurality of vias 112a-112c, and a through-dielectric via (TDV) 114. In some embodiments, the silicon photonic chip 100 may include additional layers, fewer layers, different layers, and/or the like as compared to the layers shown in FIG. 1A.

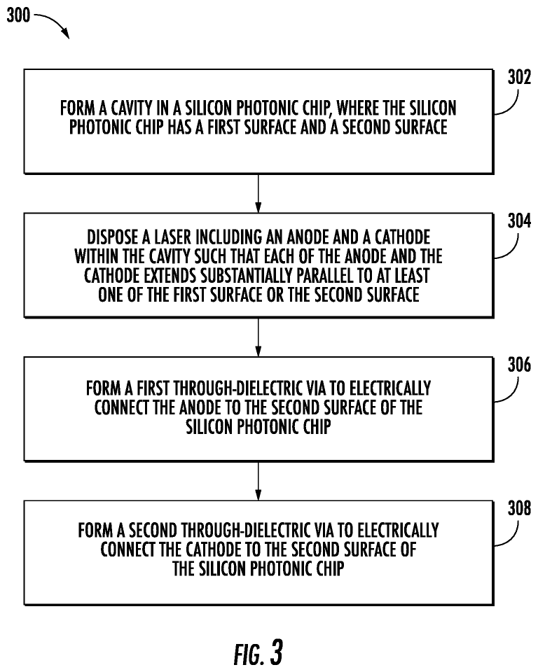

As shown in FIG. 1A, the buried oxide layer 104 may be formed on an upper surface of the bulk silicon layer 102. In this regard, the bulk silicon layer 102 may serve as a base for forming the layers of the silicon photonic chip 100 and, as described herein with respect to FIG. 3, may be removed such that the buried oxide layer 104 is the bottommost layer of the silicon photonic chip 100.

As shown in FIG. 1A, the silicon waveguide layer 106 may be formed on an upper surface of the buried oxide layer 104. In some embodiments, the silicon waveguide layer 106 may include one or more waveguides configured to transmit and/or modify optical signals provided to the silicon waveguide layer 106. As will be appreciated by one of ordinary skill in the art in view of the present disclosure, the silicon waveguide layer 106 may have a non-uniform shape in planes parallel to the upper surface of the buried oxide layer 104, where the non-uniform shape is configured to form the one or more waveguides and confine light within the one or more waveguides. The silicon waveguide layer 106 may optically connect one or more optical components (not shown) of the silicon photonic chip 100 and/or one or more opto-electrical components of the silicon photonic chip 100.

As shown in FIG. 1A, the dielectric encapsulation layer 108 may be formed on an upper surface of the silicon waveguide layer 106. In some embodiments, the dielectric encapsulation layer 108 may include one or more layers of silicon nitride and may be referred to as a back-end-of-line dielectric layer. The dielectric encapsulation layer 108 may isolate metal elements, such as the metal layers 110a-110d and the vias 112a-112c, from the silicon waveguide layer 106. Additionally, or alternatively, the dielectric encapsulation layer 108 may isolate metal elements (e.g., the metal layers 110a-110d and/or the like) of the silicon photonic chip 100 from each other.

As shown in FIG. 1A, the plurality of metal layers 110a-110d may extend substantially parallel to an upper surface and/or a lower surface of the silicon photonic chip 100 and through a portion of the silicon photonic chip 100. In particular, the plurality of metal layers 110a-110d may be positioned within the dielectric encapsulation layer 108. Although FIG. 1A shows four metal layers 110a-110d, the silicon photonic chip 100 may include more than four metal layers or fewer than four metal layers. Furthermore, the metal layers 110a-110d may extend only through particular portions of the silicon photonic chip 100, such as certain widths and depths of the silicon photonic chip 100 in the orientation depicted in FIG. 1A. In some embodiments, the metal layers 110a-110d may have a particular shape, pattern, size, orientation, configuration, and/or the like within the dielectric encapsulation layer 108 to provide electrical connections between different electronic components of the silicon photonic chip 100. For example, the metal layers 110a-110d and the vias 112a-112c may form one or more integrated circuits.

As shown in FIG. 1A, the plurality of vias 112a-112c may each extend between and electrically connect two or more metal layers. For example, and as shown in FIG. 1A, via 112a extends between and electrically connects metal layers 110a and 110b; via 112b extends between and electrically connects metal layers 110b and 110c; and via 112c extends between and electrically connects metal layers 110c and 110d. In this regard, the vias 112a-112c may be referred to as intra-metal vias. Although FIG. 1A shows three vias 112a-112c, the silicon photonic chip 100 may include more than three vias or fewer than three vias. In some embodiments, the vias 112a-112c may have a particular shape, pattern, size, orientation, configuration, and/or the like within the dielectric encapsulation layer 108 to provide electrical connections between different metal layers and/or electronic components of the silicon photonic chip 100.

In the example depicted in FIG. 1A, the TDV 114 extends from the metal layer 110d through a portion of the dielectric encapsulation layer 108, through the silicon waveguide layer 106, and through the buried oxide layer 104. In this regard, after the bulk silicon layer 102 has been removed as described herein with respect to FIG. 3, the TDV 114 may electrically connect the metal layer 110d to a bottom surface 100a of the silicon photonic chip 100 (e.g., the bottom surface of the buried oxide layer 104). In some embodiments, the TDV 114 may be a vertical pillar of conductive material within the silicon photonic chip 100.

As will be appreciated by one of ordinary skill in the art in view of the present disclosure, the TDV 114 may extend from a different metal layer, such as one of metal layers 110a-110c, to the bottom surface 100a of the silicon photonic chip 100, in some embodiments. Furthermore, when the TDV 114 extends from a metal layer that does not correspond to the bottommost layer in the dielectric encapsulation layer 108, the other metal layers may be configured to be electrically isolated from the TDV 114 (e.g., by having particular shapes, patterns, sizes, orientations, configurations, and/or the like within the dielectric encapsulation layer 108 to avoid contact and/or electrical coupling with the TDV 114).

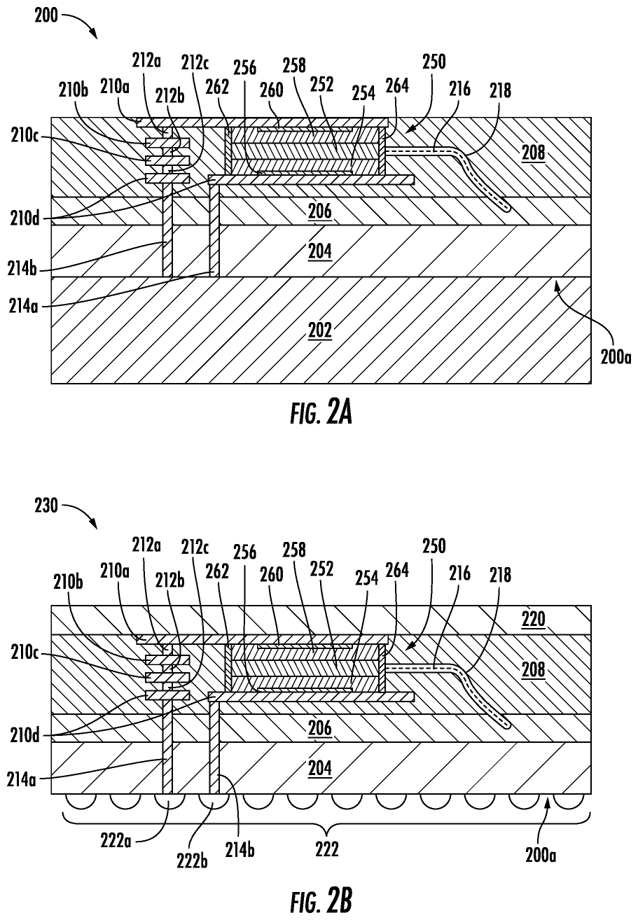

As will also be appreciated by one of ordinary skill in the art in view of the present disclosure, the silicon photonic chip 100 may include additional TDVs as compared to that shown in FIG. 1A. For example, and as will be described with respect to FIGS. 2A and 2B, the silicon photonic chip 100 may include two TDVs extending from two different metal layers to the bottom surface 100a of the silicon photonic chip 100. However, the silicon photonic chip 100 may, in other embodiments, include three or more TDVs extending from extending from three or more different metal layers to the bottom surface 100a of the silicon photonic chip 100.

As shown in FIG. 1A, the TDV 114 may extend through a portion of the dielectric encapsulation layer 108, through the silicon waveguide layer 106, and through the buried oxide layer 104. Thus, the TDV 114 may extend through both dielectric and silicon materials. In this regard, and as will be appreciated by one of ordinary skill in the art in view of the present disclosure, the TDVs of the silicon photonic chip 100 may be referred to as TDVs or through-silicon vias (TSVs). Furthermore, and as will also be appreciated by one of ordinary skill in the art in view of the present disclosure, the TDVs of the silicon photonic chip 100 may be generally referred to as through-vias. In some embodiments, TSVs may have a length of about 90-100 microns, and TDVs may have a length of less than about 10 microns.

FIG. 1B is a cross-sectional view of a layer stack for a laser 150, in accordance with an embodiment of the invention. As shown in FIG. 1B, the laser 150 may include an active region 152, a first contact region 154, a first contact 156, a second contact region 158, a second contact 160, a first mirror region 162, and a second mirror region 164. In some embodiments, the laser 150 may include additional regions, contacts, mirrors and/or the like as compared to those shown in FIG. 1B.

As shown in FIG. 1B, the active region 152 may be disposed between the first contact region 154 and the second contact region 158. In some embodiments, the active region 152 may include, for example, one or more quantum wells formed from quantum well layers. Additionally, or alternatively, the active region 152 may be configured to generate light when a voltage bias is applied to the first contact 156 and the second contact 160. For example, the laser 150 may be a PN diode, and applying a voltage bias such that current flows downward (with respect to the configuration shown in FIG. 1B) across the active region 152 may cause amplified spontaneous emission of light laterally in a direction orthogonal to the direction of current flow.

In some embodiments, the first contact region 154 may be a p-doped region and may extend substantially parallel to the active region 152 between the first mirror region 162 and the second mirror region 164. The first contact 156 may be a metal layer forming an anode for the laser 150.

In some embodiments, the second contact region 158 may be an n-doped region and may extend substantially parallel to the active region 152 between the first mirror region 162 and the second mirror region 164. The second contact 160 may be a metal layer forming an anode for the laser 150.

As shown in FIG. 1B, the first mirror region 162 may be disposed on a first side (e.g., a left side with respect to the configuration shown in FIG. 1B) of the first contact region 154, the second contact region 158, and the active region 152, and the second mirror region 164 may be disposed on a second side (e.g., a right side with respect to the configuration shown in FIG. 1B) opposite the first side of the first contact region 154, the second contact region 158, and the active region 152. In some embodiments, the first mirror region 162 may include a material with high reflectivity (e.g., 95% or greater, 97% or greater, or 99% or greater) and the second mirror region 164 may include a thin film dielectric with a reflectivity tuned between 0% and 100% (e.g., by adjusting a thickness and/or a number of thin film layers) based on the design of the laser 150 to achieve a desired laser performance. For example, the first mirror region 162 may include a metal reflective coating, such as gold or aluminum, and the second mirror region 164 may include thin-film dielectrics, etched gratings in the laser 150, and/or the like. After being confined within the active region 152 by the first mirror region 162 and the second mirror region 164, light generated by the active region 152 may pass through the second mirror region 164 due to the comparatively lower reflectivity of the second mirror region 164. In this regard, the laser 150 may be configured to emit light in a direction substantially parallel to the direction in which the active region 152 extends (e.g., horizontally to the right in the orientation depicted in FIG. 1B).

As shown in FIG. 1B, the first contact 156 may be positioned on a bottom surface of the first contact region 154 and/or the laser 150, and the second contact 160 may be positioned on a top surface of the second contact region 158 and/or the laser 150. In this regard, the configuration and/or orientation of the laser 150 is such that the contacts are positioned in a manner such that current flows vertically through the laser 150 and light is emitted horizontally (e.g., light is emitted perpendicular to the direction of current flow). Such a configuration and/or orientation achieves optimal performance of the laser 150 in various applications as compared to alternative configurations and/or orientations.

FIG. 2A is a cross-sectional view of a layer stack for a silicon photonic chip 200 with an embedded laser 250, in accordance with an embodiment of the invention. As shown in FIG. 2A, the silicon photonic chip 200 may include a bulk silicon layer 202, a buried oxide layer 204, a silicon waveguide layer 206, and a dielectric encapsulation layer 208. As also shown in FIG. 2A, the silicon photonic chip 200 may include a plurality of metal layers 210a-210d, a plurality of vias 212a-212c, a pair of TDVs 214a and 214b, a light emission path 216, and a waveguide 218.

In some embodiments, the silicon photonic chip 200, the bulk silicon layer 202, the buried oxide layer 204, the silicon waveguide layer 206, and the dielectric encapsulation layer 208 may be similar to the silicon photonic chip 100, the bulk silicon layer 102, the buried oxide layer 104, the silicon waveguide layer 106, and the dielectric encapsulation layer 108, respectively, shown and described herein with respect to FIG. 1A. Additionally, or alternatively, the metal layers 210a-210d, the plurality of vias 212a-212c, and each TDV of the pair of TDVs 214a and 214b may be similar to the metal layers 110a-110d, the plurality of vias 112a-112c, and the TDV 214, respectively, shown and described herein with respect to FIG. 1A.

As shown in FIG. 2A, the silicon photonic chip 200 may include the laser 250 embedded in the dielectric encapsulation layer 208. The laser 250 may include an active region 252, a first contact region 254, a first contact 256, a second contact region 258, a second contact 260, a first mirror region 262, and a second mirror region 264. In some embodiments, the laser 250, the active region 252, the first contact region 254, the first contact 256, the second contact region 258, the second contact 260, the first mirror region 262, and the second mirror region 264 may be similar to the laser 150, the active region 152, the first contact region 154, the first contact 156, the second contact region 158, the second contact 160, the first mirror region 162, and the second mirror region 164, respectively, shown and described herein with respect to FIG. 1B.

As shown in FIG. 2A, the first contact 256 may be electrically connected to the metal layer 210d, and the second contact 260 may be electrically connected to the metal layer 210a. In this regard, the metal layer 210d may electrically connect the first contact 256 to the TDV 214a, and the metal layer 210a may electrically connect the second contact 260 to the TDV 214b (e.g., with the vias 212a-212c). In some embodiments, the first contact 256 and the second contact 260 may be electrically connected to the TDV 214a and the TDV 214b, respectively, via different metal layers of the silicon photonic chip 200.

As shown in FIG. 2A, the laser 250 may emit light through the second mirror region 264, and the waveguide 218 may receive and guide the light to the silicon waveguide layer 206 along the light emission path 216. In this regard, the waveguide 218 may be formed within the dielectric encapsulation layer 108 and at least a portion of the silicon waveguide layer 106. In some embodiments, the silicon photonic chip 200 may include one or more waveguides and/or optical elements (e.g., optical fibers, optical glass, mirrors, lenses, and/or the like) configured to receive and guide light emitted by the laser 250 into the silicon waveguide layer 206.

In this way, the laser 250 may be configured and/or oriented in the silicon photonic chip 200 such that the contacts are positioned in a manner such that current flows vertically through the laser 250 and light is emitted horizontally (e.g., light is emitted perpendicular to the direction of current flow). As noted, such a configuration and/or orientation achieves optimal performance of the laser 250 for certain applications as compared to alternative configurations and/or orientations.

FIG. 2B is a cross-sectional view of a layer stack of a chip package 230 including the silicon photonic chip 200 with the embedded laser 250 of FIG. 2A, in accordance with an embodiment of the invention. As shown in FIG. 2B, the chip package 230 includes a protective oxide layer 220 and a plurality of metal contacts 222 (e.g., 222a, 222b, etc.).

In some embodiments, and as shown in FIG. 2B, the protective oxide layer 220 may be formed on the top surface of the dielectric encapsulation layer 208. The protective oxide layer 220 may prevent damage to and oxidation of the components of the chip package 230 (e.g., the embedded laser 250 and its components, the metal layers 210-210d, the metal vias 212a-212b, the TDVs 214a and 214b, the dielectric encapsulation layer 208, the silicon waveguide layer 206, and/or the like).

As also shown in FIG. 2B, the bulk silicon layer 202 has been removed as described herein with respect to FIG. 3. Furthermore, the TDVs 114a and 114b may electrically connect the second contact 260 and the first contact 256, respectively, to the bottom surface 200a of the chip package 230 (e.g., the bottom surface of the buried oxide layer 204). In particular, the TDV 214a, the metal layer 210a, and the vias 212a-212c may electrically connect the second contact 260 (e.g., the cathode) to a metal contact 222a on the bottom surface 200a of the chip package 230. Similarly, the TDV 214b and the metal layer 210d may electrically connect the first contact 256 (e.g., the anode) to a metal contact 222b on the bottom surface 200a of the chip package 230.

By electrically connecting the first contact 256 and the second contact 260 of the laser 250 to the bottom surface 200a of the chip package 230 and the metal contacts 222a and 222b, respectively, the chip package 230 may be reflow soldered onto a carrier substrate (e.g., a printed circuit board), where external biases can be applied to drive the laser 250. Furthermore, as noted, connecting the first contact 256 and the second contact 260 of the laser 250 to the bottom surface 200a of the chip package 230 permits the laser 250 to be configured and/or oriented in the chip package 230 in a manner that achieves optimal performance of the laser 250.

In some embodiments, the silicon photonic chip 200 and/or the chip package 230 may be an optical interposer (e.g., an optical interface for an electrical circuit). Additionally, or alternatively, an opto-electrical device may include the silicon photonic chip 200 and/or the chip package 230 and may be (i) electrically connected to the laser 250 via the TDVs 214a and 214b and (ii) optically connected to the laser 250 via one or more waveguides.

FIG. 3 is a flowchart illustrating a method 300 of manufacturing a silicon photonic chip, in accordance with an embodiment of the invention. In some embodiments, the silicon photonic chip may be similar to one or more of the silicon photonic chips and/or chip packages described herein, such as the silicon photonic chip 100 of FIG. 1A, the silicon photonic chip 200 of FIG. 2A, and/or the chip package 230 of FIG. 2B.

As shown in block 302, the method 300 may include forming a cavity in a silicon photonic chip, where the silicon photonic chip has a first surface and a second surface. For example, the silicon photonic chip may include a dielectric encapsulation layer between the first surface of the silicon photonic chip and the second surface of the silicon photonic chip, and the method may include, when forming the cavity, forming the cavity in the dielectric encapsulation layer.

As shown in block 304, the method 300 may include disposing a laser including an anode and a cathode within the cavity such that each of the anode and the cathode extends substantially parallel to at least one of the first surface or the second surface of the silicon photonic chip. In some embodiments, disposing the laser within the cavity may include disposing the laser within the cavity such that an emission axis of the laser is substantially parallel to at least one of the first surface or the second surface of the silicon photonic chip.

As shown in block 306, the method 300 may include forming a first TDV to electrically connect the anode to the second surface of the silicon photonic chip. For example, the method 300 may include performing a deep isotropic etch in a silicon material and/or a dielectric material to bore out a hole in the silicon material and/or the dielectric material, filling the hole with metal, and capping the hole with contacts. In some embodiments, the method 300 may include forming a first metal layer in the silicon photonic chip, where the first metal layer extends substantially parallel to at least one of the first surface or the second surface, and where the first metal layer is electrically connected to the anode and the first TDV.

As shown in block 308, the method 300 may include forming a second TDV to electrically connect the cathode to the second surface of the silicon photonic chip. In some embodiments, the method 300 may include forming a second metal layer in the silicon photonic chip, where the second metal layer extends substantially parallel to at least one of the first surface or the second surface, and where the second metal layer is electrically connected to the cathode and the second TDV.

Additionally, or alternatively, the silicon photonic chip may include a silicon waveguide layer extending substantially parallel to at least one of the first surface or the second surface, and the method 300 may include forming one or more waveguide structures in the silicon photonic chip, where the one or more waveguide structures are configured to direct light emitted by the laser into the silicon waveguide layer. For example, the one or more waveguide structures may be similar to the waveguide 218 shown and described herein with respect to FIGS. 2A and 2B. In some embodiments, the one or more waveguide structures may be formed by performing a topological partial etch of a top silicon region to provide in-plane confinement of the optical mode of light emitted by the laser.

In some embodiments, the silicon photonic chip may be formed on a silicon substrate adjacent the second surface, and the method 300 may include removing the silicon substrate from the second surface and forming metal contacts on the second surface, where a first metal contact of the metal contacts is electrically connected to the first through-dielectric via, and where a second metal contact of the metal contacts is electrically connected to the second through-dielectric via. Additionally, or alternatively, the method 300 may include reflow soldering the metal contacts to electrically and mechanically connect the silicon photonic chip to a printed circuit board.

Method 300 may include additional embodiments, such as any single embodiment or any combination of embodiments described herein. Although FIG. 3 shows example blocks of method 300, in some embodiments, method 300 may include additional blocks, fewer blocks, different blocks, or differently arranged blocks than those depicted in FIG. 3. Additionally, or alternatively, two or more of the blocks of method 300 may be performed in parallel.

As will be appreciated by one of ordinary skill in the art in view of this disclosure, the present invention may include and/or be embodied as an apparatus (including, for example, a system, a machine, a device, and/or the like), as a method (including, for example, a manufacturing method, a robot-implemented process, and/or the like), or as any combination of the foregoing.

Although many embodiments of the present invention have just been described above, the present invention may be embodied in many different forms and should not be construed as limited to the embodiments set forth herein; rather, these embodiments are provided so that this disclosure will satisfy applicable legal requirements. Also, it will be understood that, where possible, any of the advantages, features, functions, devices, and/or operational aspects of any of the embodiments of the present invention described and/or contemplated herein may be included in any of the other embodiments of the present invention described and/or contemplated herein, and/or vice versa.

While certain exemplary embodiments have been described and shown in the accompanying drawings, it is to be understood that such embodiments are merely illustrative of and not restrictive on the broad invention, and that this invention is not limited to the specific constructions and arrangements shown and described, since various other changes, combinations, omissions, modifications, and substitutions, in addition to those set forth in the above paragraphs, are possible. Those skilled in the art will appreciate that various adaptations, modifications, and combinations of the just described embodiments may be configured without departing from the scope and spirit of the invention. For example, devices, modules, components, and/or elements shown in the figures are not necessarily drawn to scale and may vary from that shown without departing from the scope and spirit of the invention. Therefore, it is to be understood that, within the scope of the appended claims, the invention may be practiced other than as specifically described herein.

What is claimed is:

1. A silicon photonic chip, comprising:
a laser disposed in the silicon photonic chip between a first surface of the silicon photonic chip and a second surface of the silicon photonic chip, wherein the laser comprises an anode and a cathode, wherein each of the anode and the cathode extends substantially parallel to at least one of the first surface or the second surface through at least a portion of the silicon photonic chip;
a first through-dielectric via electrically connecting the anode to the second surface of the silicon photonic chip; and
a second through-dielectric via electrically connecting the cathode to the second surface of the silicon photonic chip.

2. The silicon photonic chip of claim 1, wherein the laser is configured to emit light into the silicon photonic chip between the first surface and the second surface.

3. The silicon photonic chip of claim 1, wherein the laser is configured to emit light in a direction substantially parallel to at least one of the first surface or the second surface.

4. The silicon photonic chip of claim 1, wherein the laser comprises:
an n-doped region extending substantially parallel to the second surface and through at least a portion of the silicon photonic chip;
a p-doped region extending substantially parallel to the second surface and through at least a portion of the silicon photonic chip; and
an active region disposed between the n-doped region and the p-doped region, wherein the active region extends substantially parallel to the second surface and through at least a portion of the silicon photonic chip, and wherein the active region is configured to generate light.

5. The silicon photonic chip of claim 4, wherein the laser comprises:
a first mirror region on a first side of the n-doped region, the p-doped region, and the active region; and
a second mirror region on a second side of the n-doped region, the p-doped region, and the active region, wherein the second side is opposite the first side.

6. The silicon photonic chip of claim 1, comprising a silicon waveguide layer disposed within the silicon photonic chip, wherein the silicon waveguide layer extends substantially parallel to at least one of the first surface or the second surface, and wherein the silicon waveguide layer is configured to receive and guide light emitted by the laser.

7. The silicon photonic chip of claim 6, comprising one or more waveguide structures disposed within the silicon photonic chip, wherein the one or more waveguide structures are configured to direct the light emitted by the laser into the silicon waveguide layer.

8. The silicon photonic chip of claim 1, comprising:
a first metal layer extending substantially parallel to at least one of the first surface or the second surface and through at least a portion of the silicon photonic chip, wherein the first metal layer is electrically connected to the anode and the first through-dielectric via; and
a second metal layer extending substantially parallel to at least one of the first surface or the second surface and through at least a portion of the silicon photonic chip, wherein the second metal layer is electrically connected to the cathode and the second through-dielectric via.

9. The silicon photonic chip of claim 1, comprising:
a plurality of metal layers extending substantially parallel to at least one of the first surface or the second surface and through at least a portion of the silicon photonic chip; and
at least one intra-metal via disposed within the silicon photonic chip and electrically connecting two or more metal layers of the plurality of metal layers;
wherein the plurality of metal layers and the at least one intra-metal via form one or more integrated circuits.

10. The silicon photonic chip of claim 1, comprising a dielectric encapsulation layer between the first surface of the silicon photonic chip and the second surface of the silicon photonic chip, wherein the laser is disposed within the dielectric encapsulation layer.

11. The silicon photonic chip of claim 1, comprising a buried oxide layer, wherein the buried oxide layer defines the second surface, and wherein the first through-dielectric via and the second through-dielectric via extend through the buried oxide layer.

12. The silicon photonic chip of claim 1, comprising metal contacts on the second surface of the silicon photonic chip, wherein a first metal contact of the metal contacts is electrically connected to the first through-dielectric via, and wherein a second metal contact of the metal contacts is electrically connected to the second through-dielectric via.

13. The silicon photonic chip of claim 1, comprising a protective oxide layer, wherein the protective oxide layer defines the first surface.

14. The silicon photonic chip of claim 1, wherein the silicon photonic chip is an optical interposer.

15. An opto-electrical device comprising the silicon photonic chip of claim 1, wherein the opto-electrical device is electrically connected to the laser via the first through-dielectric via and the second through-dielectric via, and wherein the opto-electrical device is optically connected to the laser via one or more waveguides.

16. A method of manufacturing a silicon photonic chip, the method comprising:
forming a cavity in a silicon photonic chip, wherein the silicon photonic chip has a first surface and a second surface;
disposing a laser comprising an anode and a cathode within the cavity such that each of the anode and the cathode extends substantially parallel to at least one of the first surface or the second surface;
forming a first through-dielectric via to electrically connect the anode to the second surface of the silicon photonic chip; and
forming a second through-dielectric via to electrically connect the cathode to the second surface of the silicon photonic chip.

17. The method of claim 16, wherein disposing the laser within the cavity comprises disposing the laser within the cavity such that an emission axis of the laser is substantially parallel to at least one of the first surface or the second surface.

18. The method of claim 16, comprising:
forming a first metal layer in the silicon photonic chip, wherein the first metal layer extends substantially parallel to at least one of the first surface or the second surface, and wherein the first metal layer is electrically connected to the anode and the first through-dielectric via; and
forming a second metal layer in the silicon photonic chip, wherein the second metal layer extends substantially parallel to at least one of the first surface or the second surface, and wherein the second metal layer is electrically connected to the cathode and the second through-dielectric via.

19. The method of claim 16, wherein the silicon photonic chip comprises a dielectric encapsulation layer between the first surface of the silicon photonic chip and the second surface of the silicon photonic chip, and wherein the method comprises, when forming the cavity, forming the cavity in the dielectric encapsulation layer.

20. The method of claim 16, wherein the silicon photonic chip comprises a silicon waveguide layer extending substantially parallel to at least one of the first surface or the second surface, and wherein the method comprises forming one or more waveguide structures in the silicon photonic chip, wherein the one or more waveguide structures are configured to direct light emitted by the laser into the silicon waveguide layer.

21. The method of claim 16, wherein the silicon photonic chip is formed on a silicon substrate adjacent the second surface, and wherein the method comprises:
removing the silicon substrate from the second surface; and
forming metal contacts on the second surface, wherein a first metal contact of the metal contacts is electrically connected to the first through-dielectric via, and wherein a second metal contact of the metal contacts is electrically connected to the second through-dielectric via.

22. The method of claim 21, comprising reflow soldering the metal contacts to electrically and mechanically connect the silicon photonic chip to a printed circuit board.
